(19) United States
(12) Patent Application Publication
(10) Pub. No.: US 2024/0258309 A1
(43) Pub. Date: Aug. 1, 2024

(54) SEMICONDUCTOR DEVICE

(71) Applicant: FUJI ELECTRIC CO., LTD., Kawasaki-shi (JP)

(72) Inventor: Takahide TANAKA, Matsumoto-city (JP)

(73) Assignee: FUJI ELECTRIC CO., LTD., Kawasaki-shi (JP)

(21) Appl. No.: 18/519,301

(22) Filed: Nov. 27, 2023

(30) Foreign Application Priority Data
Jan. 31, 2023 (JP) 2023-013496

(51) Int. Cl. H01L 27/088; H01L 27/06; H01L 29/10; H01L 29/66; H01L 29/78; H03K 17/04; H03K 19/0175

(52) U.S. Cl. CPC H01L 27/088; H01L 27/0635; H01L 29/1095; H01L 29/66325; H01L 29/7835; H03K 17/0406; H03K 19/017518; H03K 2217/0063; H03K 2217/0072

(57) ABSTRACT

A semiconductor device includes: a substrate body of a first conductivity-type; a first well region of a second conductivity-type provided in the substrate body and provided with a high-side circuit; a first voltage blocking region of the second conductivity-type provided around the first well region; a contact region of the second conductivity-type provided at an upper part of the first well region or the first voltage blocking region; a second voltage blocking region of the first conductivity-type provided on an outer circumferential side of the first voltage blocking region so as to be in contact with the first voltage blocking region; a first isolation region of the first conductivity-type provided to electrically isolate, from the first well region, an opposed part of the first voltage blocking region opposed to a low-side circuit provided on an outer circumferential side of the second voltage blocking region; and a level shifter.

### CROSS-REFERENCE TO RELATED APPLICATION

This application claims benefit of priority under 35 USC 119 based on Japanese Patent Application No. 2023-013496 filed on Jan. 31, 2023, the entire contents of which are incorporated by reference herein.

### BACKGROUND OF THE INVENTION

### 1. Field of the Invention

The present invention relates to semiconductor devices.

### 2. Description of the Related Art

JP H09-283716 A (FIG. 8) discloses a high-breakdown-voltage semiconductor device including a p⁻-silicon substrate, an n⁻-type diffusion region formed into a circular shape on the p⁻-silicon substrate, an n-diffusion region formed into a circular shape in contact with the inner side of the n⁻-type diffusion region, and an n-diffusion region formed into a land-like state so as to interpose the p⁻-substrate having a predetermined width inside the n-diffusion region.

JP 2018-46685 A (FIG. 1) discloses a semiconductor device having a configuration including a termination region that is an n⁻-type semiconductor region provided to surround a high-side region, and a region provided with a level-shift transistor arranged at a position opposed to a low-side region in the termination region.

JP 6798377 B2 (FIG. 13) discloses a HVIC including high-side circuit regions for three phases and two low-side circuit regions, wherein the low-side circuit regions are arranged to be opposed to the sides of the high-side circuit regions not provided with VB pickup regions.

The conventional HVJTs have a problem with a phenomenon in which a potential of the n-type well region that is led to be the same potential as a VB potential or a VS potential applied to the high-side circuit rises up when the VB potential or the VS potential steeply rises up due to an electrostatic discharge (ESD) or the like, and a substrate potential immediately under the n-type well region further rises up in association with a flow of a displacement current.

If the low-side circuit is located close to this n-type well region, a fluctuation of the substrate potential is transmitted to induce a parasitic operation, which could lead to a reduction in noise tolerance such as ESD tolerance.

### SUMMARY OF THE INVENTION

In view of the foregoing problems, the present invention provides a semiconductor device having a configuration capable of avoiding a reduction in noise tolerance.

An aspect of the present invention inheres in a semiconductor device including: a substrate body of a first conductivity-type; a first well region of a second conductivity-type provided in the substrate body and provided with a high-side circuit; a first voltage blocking region of the second conductivity-type provided around the first well region and having a lower impurity concentration than the first well region; a contact region of the second conductivity-type provided in the first well region or the first voltage blocking region and having a higher impurity concentration than the first well region; a second voltage blocking region of the first conductivity-type provided on an outer circumferential side of the first voltage blocking region so as to be in contact with the first voltage blocking region; a first isolation region of the first conductivity-type provided to electrically isolate, from the first well region, an opposed part of the first voltage blocking region opposed to a low-side circuit provided on an outer circumferential side of the second voltage blocking region; and a level shifter provided to execute a signal transmission between the low-side circuit and the high-side circuit.

### BRIEF DESCRIPTION OF THE DRAWINGS

FIG. 1 is a circuit diagram illustrating a semiconductor device according to a first embodiment;

FIG. 2 is a plan view illustrating the semiconductor device according to the first embodiment;

FIG. 3A is a cross-sectional view taken along line A-A′ in FIG. 2;

FIG. 3B is a cross-sectional view illustrating a region including a resistor according to the first embodiment which is a polysilicon resistor;

FIG. 3C is a cross-sectional view illustrating a region including a resistor according to the first embodiment which is a diffusion resistor;

FIG. 4 is a plan view illustrating a semiconductor device of a comparative example of the first embodiment;

FIG. 5 is a cross-sectional view taken along line A-A′ in FIG. 4;

FIG. 6 is a plan view illustrating a semiconductor device according to a second embodiment;

FIG. 7 is a cross-sectional view taken along line B-B′ in FIG. 6;

FIG. 8 is a plan view illustrating a semiconductor device of a comparative example of the second embodiment;

FIG. 9 is a plan view illustrating a semiconductor device according to a third embodiment;

FIG. 10 is a plan view illustrating a semiconductor device of a comparative example of the third embodiment;

FIG. 11A is a plan view illustrating a semiconductor device according to a fourth embodiment;

FIG. 11B is a cross-sectional view illustrating a region including a resistor according to the fourth embodiment;

FIG. 12 is a plan view illustrating a semiconductor device according to a fifth embodiment;

FIG. 13 is a plan view illustrating a semiconductor device of a comparative example of the fifth embodiment;

FIG. 14 is a plan view illustrating a semiconductor device according to a sixth embodiment; and

FIG. 15 is a cross-sectional view illustrating a semiconductor device according to a seventh embodiment.

### DETAILED DESCRIPTION

With reference to the drawings, first to seventh embodiments of the present invention will be described below.

In the drawings, the same or similar elements are indicated by the same or similar reference numerals. The drawings are schematic, and it should be noted that the relationship between thickness and planer dimensions, the thickness proportion of each layer, and the like are different from real ones. Accordingly, specific thicknesses or dimensions should be determined with reference to the following description. Moreover, in some drawings, portions are illustrated with different dimensional relationships and proportions. The first to seventh embodiments described below merely illustrate schematically devices and methods for specifying and giving shapes to the technical idea of the present invention, and the span of the technical idea is not limited to materials, shapes, structures, and relative positions of elements described herein.

In the specification, a “carrier-supply region” means a semiconductor region which supplies majority carriers as a main current. The carrier-supply region is assigned to a semiconductor region which will be a source region in a field-effect transistor (FET) or a static induction transistor (SIT), an emitter region in an insulated-gate bipolar transistor (IGBT), and an anode region in a static induction (SI) thyristor or a gate turn-off (GTO) thyristor. A “carrier-reception region” means a semiconductor region which receive the majority carriers as the main current. The carrier-reception region is assigned to a semiconductor region which will be the drain region in the FET or the SIT, the collector region in the IGBT, and the cathode region in the SI thyristor or GTO thyristor.

In the specification, definitions of directions such as an up-and-down direction in the following description are merely definitions for convenience of understanding, and are not intended to limit the technical ideas of the present invention. For example, as a matter of course, when the subject is observed while being rotated by 90°, the subject is understood by converting the up-and-down direction into the right-and-left direction. When the subject is observed while being rotated by 180°, the subject is understood by inverting the up-and-down direction.

In the specification, there is exemplified a case where a first conductivity-type is an p-type and a second conductivity-type is a n-type. However, the relationship of the conductivity-types may be inverted to set the first conductivity-type to the n-type and the second conductivity-type to the p-type. Further, a semiconductor region denoted by the symbol “n” or “p” attached with “+” indicates that such semiconductor region has a relatively high impurity concentration as compared to a semiconductor region denoted by the symbol “n” or “p” without “+”. A semiconductor region denoted by the symbol “n” or “p” attached with “−” indicates that such semiconductor region has a relatively low impurity concentration as compared to a semiconductor region denoted by the symbol “n” or “p” without “−”. However, even when the semiconductor regions are denoted by the same reference symbols “n” and “n”, it is not indicated that the semiconductor regions have exactly the same impurity concentration. Moreover, the members and the regions that are limited by adding “first conductivity-type” and “second conductivity-type” in the following description indicate the members and the regions formed of semiconductor materials without particular obvious limitations.

### First Embodiment

### <Circuit of Semiconductor Device>

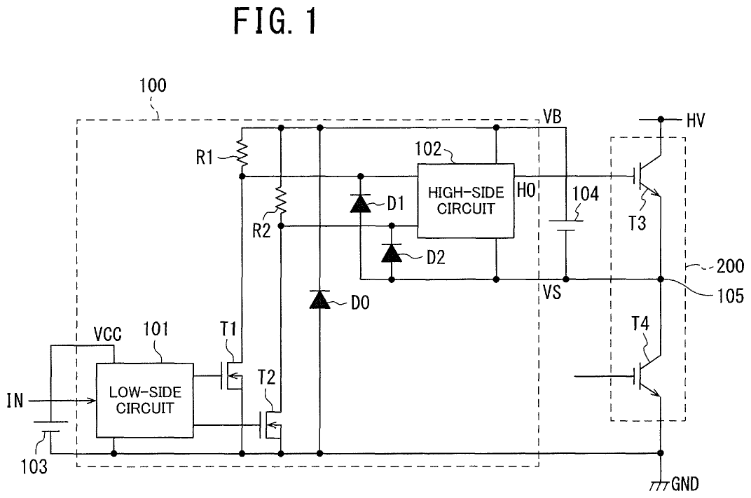

A semiconductor device according to a first embodiment is illustrated below with a case of a high-voltage integrated circuit (HVIC) 100, as illustrated in FIG. 1. The HVIC 100 drives a power conversion part 200 as a target to be driven for one phase of a bridge circuit for power conversion, for example. The power conversion part 200 includes a high-potential-side switching element T3 and a low-voltage-side switching element T4 connected in series so as to implement a half-bridge circuit. While FIG. 1 illustrates the case in which the high-potential-side switching element T3 and the low-voltage-side switching element T4 are each an IGBT, the respective elements may be any other power switching elements such as a metal-oxide-semiconductor field-effect transistor (MOSFET).

An HV potential on the high-potential side is connected to a collector of the high-potential-side switching element T3. A ground potential (a GND potential) on the low-potential side is connected to an emitter of the low-voltage-side switching element T4. A VS potential on the negative-electrode side of a power supply (a high-potential-side power supply) 104 on the high-potential side is connected to a connection point 105 between an emitter of the high-potential-side switching element T3 and a collector of the low-voltage-side switching element T4. A load (not illustrated) such as a motor is further connected to the connection point 105.

The HVIC 100 applies a drive signal, to a gate of the high-potential-side switching element T3, for turning on/off to drive the gate of the high-potential-side switching element T3 in accordance with an input signal IN from an external microcomputer, for example. The HVIC 100 includes a low-potential-side circuit (a low-side circuit) 101 and a high-potential-side circuit (a high-side circuit) 102. A VCC potential on the positive-electrode side of a power supply (a low-potential-side power supply) 103 on the low-potential side and a GND potential on the negative-electrode side of the low-potential-side power supply 103 are connected to the low-side circuit 101. Further, gates of level-shift elements (level-shifters) T1 and T2 are connected to the low-side circuit 101.

The low-side circuit 101 operates with the GND potential as a reference potential and with the VCC potential higher than the GND potential as a power-supply potential. The low-side circuit 101 generates an ON/OFF signal based on the GND potential in accordance with the input signal IN from the external microcomputer or the like, and outputs the generated signal to the respective gates of the level-shift elements T1 and T2.

The respective level-shift elements T1 and T2 execute the signal transmission between the low-side circuit 101 and the high-side circuit 102. The respective level-shift elements T1 and T2 convert the ON/OFF signal based on the GND potential from the low-side circuit 101 into an ON/OFF signal based on the VS potential, and outputs the converted ON/OFF signal to the high-side circuit 102. The respective level-shift elements T1 and T2 are each a high-breakdown-voltage n-channel MOSFET, for example.

The GND potential is connected to a source of the level-shift element T1. The high-side circuit 102 and one end of a level-shift resistor R1 are connected to a drain of the level-shift element T1. A VB potential on the positive-electrode side of the high-potential-side power supply 104 is connected to the other end of the level-shift resistor R1. A cathode of a diode D1 is connected to the drain of the level-shift element T1 and the one end of the level-shift resistor R1. The high-side circuit 102 and the VS potential on the negative-electrode side of the high-potential-side power supply 104 are connected to an anode of the diode D1. The diode D1 has a function of avoiding an excessive reduction in drain potential (Dr potential) of the level-shift element T1.

The GND potential is connected to a source of the level-shift element T2. The high-side circuit 102 and one end of a level-shift resistor R2 are connected to a drain of the level-shift element T2. The VB potential on the positive-electrode side of the high-potential-side power supply 104 is connected to the other end of the level-shift resistor R2. A cathode of a diode D2 is connected to the drain of the level-shift element T2 and the one end of the level-shift resistor R2. The high-side circuit 102 and the VS potential on the negative-electrode side of the high-potential-side power supply 104 are connected to an anode of the diode D2. The diode D2 has a function of avoiding an excessive reduction in drain potential (Dr potential) of the level-shift element T2.

A cathode of a diode D0 having a high breakdown voltage, which is referred to as a high-voltage junction termination (HVJT) diode, is connected to the respective other ends of the level-shift resistors R1 and R2 and the VB potential on the positive-electrode side of the high-potential-side power supply 104. The GND potential is connected to an anode of the diode D0.

The high-side circuit 102 operates with the VS potential as a reference potential and with the VB potential higher than the VS potential as a power-supply potential. The high-side circuit 102 outputs a drive signal based on the VS potential to the gate of the high-potential-side switching element T3 in accordance with the ON/OFF signal from the respective level-shift elements T1 and T2 so as to drive the gate of the high-potential-side switching element T3. The high-side circuit 102 includes a CMOS circuit of an n-channel MOSFET and a p-channel MOSFET at the output stage.

The VB potential is a maximum potential applied to the HVIC 100, and is kept higher than the VS potential by about 15 volts in a normal state not influenced by noise. The VS potential repeats a rise and a drop between the HV potential on the high-potential side (about 400 to 600 volts, for example) and the GND potential on the low-potential side when the high-potential-side switching element T3 and the low-voltage-side switching element T4 are complementarily turned on and off, and fluctuates between zero to several hundreds of volts. The VS potential can fall below zero.

### <Structure of Semiconductor Device>

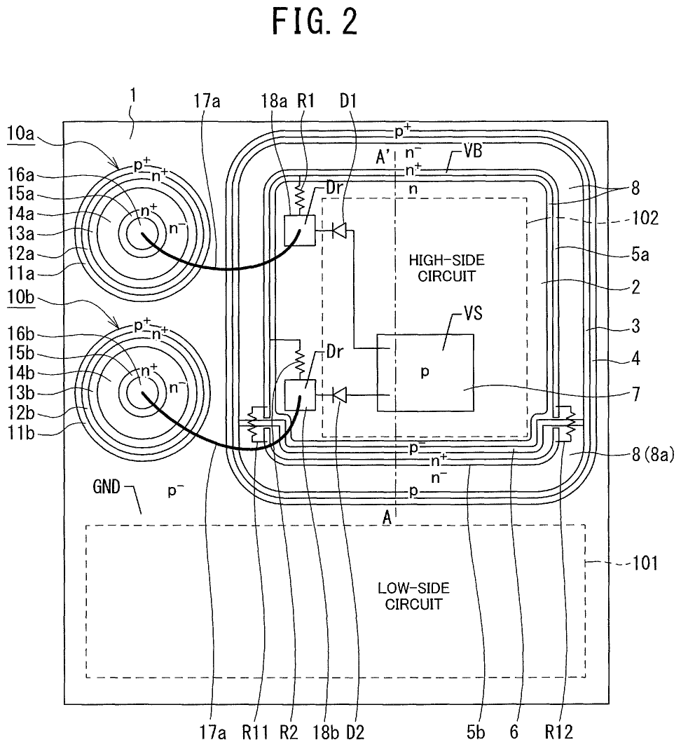

FIG. 2 illustrates a planar layout of the semiconductor device according to the first embodiment corresponding to the HVIC 100 illustrated in FIG. 1. The HVIC 100 includes a substrate body (a semiconductor chip) 1 of a first conductivity-type (p⁻-type). The substrate body 1 is made of a silicon (Si) substrate, for example. The substrate body 1 may be made of a semiconductor substrate including silicon carbide (SiC), a gallium nitride (GaN), a gallium oxide (Ga₂O₃), gallium arsenide (GaAs), or diamond (C). Alternatively, the substrate body 1 may include a semiconductor substrate of p⁻-type and an epitaxial layer of p⁻-type deposited on the semiconductor substrate.

A well region 2 of a second conductivity-type (n-type) is provided at the upper part of the substrate body 1. The well region 2 has a substantially rectangular planar pattern. The well region 2 is provided with the high-side circuit (the high-side circuit region) 102. FIG. 2 omits the illustration of the respective elements included in the high-side circuit 102.

A well region 7 of p-type is further provided at the upper part of the well region 2. The VS potential is applied to the well region 7. The respective cathodes of the diodes D1 and D2 are connected to the well region 7. The respective diodes D1 and D2 may include polysilicon provided over the substrate body 1, or may each be made of a diffusion layer provided inside the substrate body 1, for example. The semiconductor device does not necessarily include the respective diodes D1 and D2.

The well region 2 is provided with pads 18a and 18b on the top surface side. The pad 18a is connected to a VB potential of a contact region 5a via the level-shift resistor R1. The pad 18a is also connected to a VS potential of the well region 2 via the diode D1. The pad 18b is connected to the VB potential of the contact region 5a via the level-shift resistor R2. The pad 18b is also connected to the VS potential of the well region 2 via the diode D2. The respective level-shift resistors R1 and R2 include polysilicon provided on the well region 2 with an insulating film interposed, for example.

A voltage blocking region 8 of n⁻-type having a lower impurity concentration than the well region 2 is provided to surround the well region 2 in contact with each other. The voltage blocking region 8 is formed into a substantially circular state to have an external shape having a substantially rectangular planar pattern. A voltage blocking region 3 of p-type is provided into a circular state so as to further surround the outer circumference of the voltage blocking region 8. The voltage blocking region 3 formed into the substantially circular state to have an external shape having a substantially rectangular planar pattern.

The n⁺-type contact region (the pickup region) 5a is provided at the upper part of the n⁻-type voltage blocking region 8 on the outer circumferential side of the well region 2. The contact region 5a has a U-shaped planar pattern having an opening on the lower side so as to surround the circumference of the high-side circuit 102. The VB potential is applied to the contact region 5a. The contact region 5a may be provided in the well region 2. Namely, the contact region 5a is provided at the upper part of either the well region 2 or the voltage blocking region 8.

The p-n junction between the voltage blocking region 8 and the voltage blocking region 3 implements a high-voltage junction termination (HVJT) structure (3, 8). The HVJT (3, 8) corresponds to the high-breakdown-voltage diode D0 illustrated in FIG. 1. The HVJT (3, 8) is formed into a substantially circular state to have an external shape having a substantially rectangular planar pattern. The HVJT (3, 8) electrically isolates the well region 2 on the inner circumferential side of the voltage blocking region 8 from the low-side circuit (the low-side circuit region) 101 provided in the substrate body 1 on the outer circumferential side of the voltage blocking region 8. The provision of the HVJT (3, 8) allows a normal operation of the semiconductor device if the potential of the high-side circuit 102 is led to be higher than the potential of the low-side circuit 101 by several hundreds of volts.

A contact region (a pickup region) 4 of p⁺-type is provided into a circular state at the upper part of the voltage blocking region 3. The GND potential is applied to the contact region 4. The outer circumference of the voltage blocking region 3 is surrounded by the substrate body 1.

The low-side circuit 101 is provided under the high-side circuit 102 with the HVJT (3, 8) interposed in the plan view of FIG. 2. FIG. 2 omits the illustration of several kinds of elements implementing the low-side circuit 101. The respective level-shift elements 10a and 10b are arranged on the upper side of the low-side circuit 101 and on the left side of the high-side circuit 102. The level-shift elements 10a and 10b respectively correspond to the level-shift elements T1 and T2 illustrated in FIG. 1.

A method of forming the MOSFET used as the respective level-shift elements T1 and T2 illustrated in FIG. 1 is broadly divided into two methods, one of the methods being referred to as a wire-bonding method (a WB method), the other method being referred to as a self-shielding method (an SS method). The WB method forms the MOSFET independently of the HVJT to connect the drain potential (the Dr potential) of the MOSFET to the high-side circuit via bonding wires. The SS method forms the MOSFET to integrate the HVJT together.

The semiconductor device according to the first embodiment is illustrated with the case in which the respective level-shift elements 10a and 10b are formed by the WB method, as illustrated in FIG. 2. The respective level-shift elements 10a and 10b has a substantially round-shaped planar pattern. The level-shift elements 10a and 10b are each an n-channel MOSFET having a high breakdown voltage.

The level-shift element 10a includes a carrier-supply region (a source region) 12a of n⁺-type, a gate electrode 13a, a drift region 14a of n⁻-type, and a carrier-reception region (a drain region) 15a of n⁺-type. The source region 12a has a circular planar pattern. The drift region 14a is arranged on the inner circumferential side of the source region 12a, and has a circular planar pattern. The gate electrode 13a is provided over a circular-shaped base region of p-type (not illustrated) interposed between the source region 12a and the drift region 14a with a gate insulating film (not illustrated) interposed. The gate electrode 13a controls a surface potential of the base region and also controls a flow of a main current flowing between the source region 12a and the drain region 15a. The drain region 15a is provided at the upper part of the drift region 14a, and has a round-shaped planar pattern.

A drain electrode 16a is provided at the upper part of the drain region 15a. The pad 18a is connected to the drain electrode 16a via a bonding wire 17a. A base region 11a of p⁺-type is arranged on the outer circumferential side of the source region 12a. The base region 11a has a circular planar pattern.

The level-shift element 10b has the same structure as the level-shift element 10a. The level-shift element 10b includes a source region 12b of n⁺-type, a gate electrode 13b, a drift region 14b of n⁻-type, and a drain region 15b of n⁺-type. The source region 12b has a circular planar pattern. The drift region 14b is arranged on the inner circumferential side of the source region 12b, and has a circular planar pattern. The gate electrode 13b is provided over a circular-shaped base region of p-type (not illustrated) interposed between the source region 12b and the drift region 14b with a gate insulating film (not illustrated) interposed. The gate electrode 13b controls a surface potential of the base region and also controls a flow of a main current flowing between the source region 12b and the drain region 15b. The drain region 15b is provided at the upper part of the drift region 14b, and has a round-shaped planar pattern.

A drain electrode 16b is provided at the upper part of the drain region 15b. The pad 18b is connected to the drain electrode 16b via a bonding wire 17b. A base region 11b of p⁺-type is arranged on the outer circumferential side of the source region 12b. The base region 11b has a circular planar pattern.

In the semiconductor device according to the first embodiment, the voltage blocking region 8 having a substantially circular planar pattern is provided with a isolation region (a slit region) 6 of p⁻-type toward the low-side circuit 101. The isolation region 6 electrically isolates a part (an opposed part) 8a of the voltage blocking region 8 opposed to the low-side circuit 101 from the other part of the voltage blocking region 8 other than the opposed part 8a and the well region 2. FIG. 2 illustrates the case in which the isolation region 6 has a substantially U-shaped planar pattern having an opening on the upper side. The isolation region 6 may have a substantially straight planar pattern, or may have any other planar pattern determined as appropriate. The both ends of the isolation region 6 are in contact with the voltage blocking region 3.

The opposed part 8a has a U-shaped planar pattern. The opposed part 8a includes at least the middle of the part of the voltage blocking region 8 opposed to the low-side circuit 101. The opposed part 8a preferably includes all of the part of the voltage blocking region 8 opposed to the low-side circuit 101. In view of an area efficiency, the opposed part 8a is preferably composed of only the part of the voltage blocking region 8 opposed to the low-side circuit 101, since the voltage blocking region 8 needs to be expanded by the isolation region 6 when inserted into the voltage blocking region 8.

FIG. 2 illustrates the case in which the opposed part 8a encompasses two of the four corners of the rectangular planar pattern of the voltage blocking region 8 opposed to the low-side circuit 101. The opposed part 8a may be arranged to encompass only one of the two corners toward the low-side circuit 101 among the four corners of the rectangular planar pattern of the voltage blocking region 8. Alternatively, the opposed part 8a may be arranged to encompass three of the four corners of the rectangular planar pattern of the voltage blocking region 8 in total including the two corners toward the low-side circuit 101 and further one of the two corners on the opposite side of the low-side circuit 101. Alternatively, the opposed part 8a may be arranged to encompass all of the four corners of the rectangular planar pattern of the voltage blocking region 8.

A contact region (a pick-up region) 5b of n⁺-type having a higher impurity concentration than the voltage blocking region 8 is provided at the upper part of the opposed part 8a. The contact region 5b differs from the contact region 5a in not being applied directly with the VB potential. The contact region 5b is connected to the VB potential of the contact region 5a via the respective resistors R11 and R12. The resistors R11 and R12 are each a polysilicon resistor provided over the substrate body 1, for example. The opposed part 8a is led to barely follow the VB potential or the VS potential, since the opposed part 8a is isolated from the voltage blocking region 8 on the upper side by the isolation region 6 and is connected to the contact region 5a via the resistors R11 and R12.

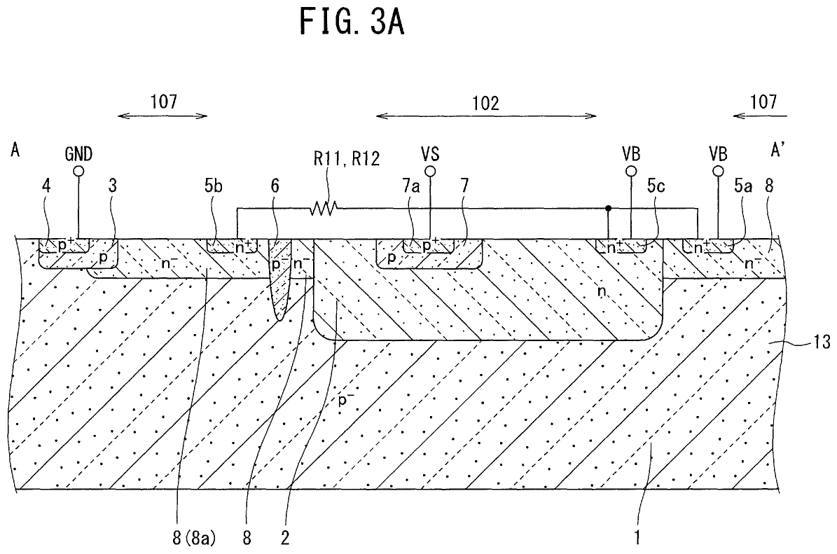

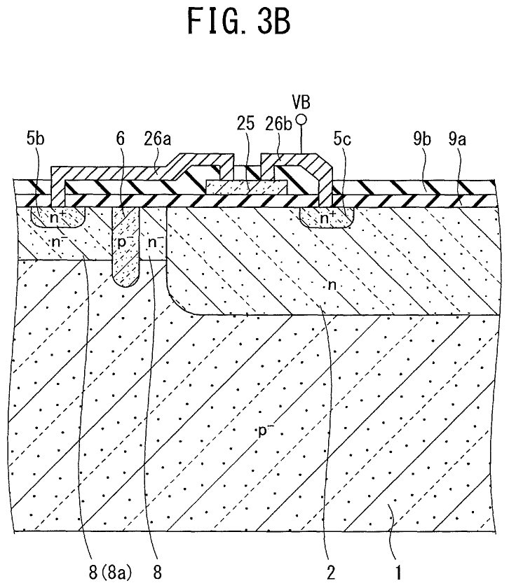

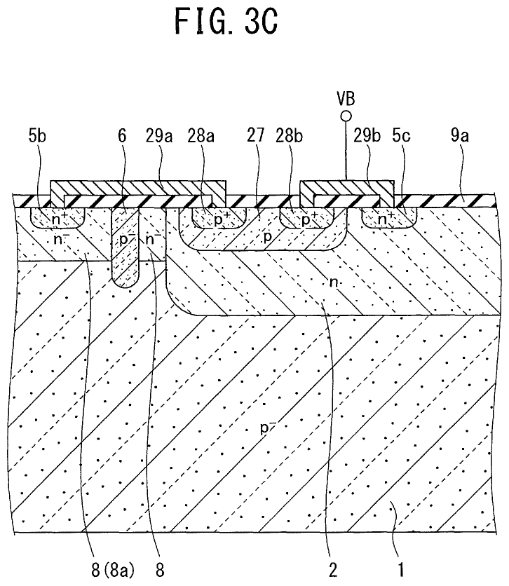

FIG. 3A is a cross-sectional view taken along line A-A′ in FIG. 2. The bottom surface of the substrate body 1 may be fixed to the GND potential. The n-type well region 2 is provided at the upper part of the p⁻-type substrate body 1. The n⁺-type contact region 5a is provided at the upper part of the well region 2. The VB potential is applied to the contact region 5a.

The p-type well region 7 is provided at the upper part of the well region 2 separately from the contact region 5a. A contact region 7a of p⁺-type is provided at the upper part of the well region 7. The VS potential is applied to the contact region 7a. FIG. 2 omits the illustration of the contact region 7a illustrated in FIG. 3A.

A contact region 5c of n⁺-type is provided at the upper part of the well region 7. The VB potential is applied to the contact region 5c. FIG. 2 omits the illustration of the contact region 5c illustrated in FIG. 3A.

The n⁻-type voltage blocking region 8 is selectively provided at the upper part of the substrate body 1 so as to be in contact with the well region 2. The voltage blocking region 8 has a shallower depth than the well region 2. The n⁺-type contact region 5b is provided at the upper part of the voltage blocking region 8. The respective contact regions 5a and 5c are connected to the contact region 5b via the respective resistors R11 and R12.

The p-type voltage blocking region 3 is selectively provided at the upper part of the substrate body 1 so as to be in contact with the voltage blocking region 8 on the opposite side of the well region 2. The p⁺-type contact region 4 is selectively provided at the upper part of the voltage blocking region 3. The GND potential is applied to the contact region 4.

The p⁻-type isolation region 6 is provided at the upper part of the substrate body 1 so as to penetrate the voltage blocking region 8 in the depth direction. The isolation region 6 has a greater depth than the voltage blocking region 8. The isolation region 6 electrically isolates the opposed part 8a of the voltage blocking region 8 opposed to the low-side circuit 101 from the well region 2.

Expanding a depletion layer from the p-n junction between the voltage blocking region 8 and the voltage blocking region 3 mainly toward a breakdown-voltage keeping region 107 of the voltage blocking region 8 keeps the breakdown voltage. The breakdown-voltage keeping region 107 is located between the p-n junction of the voltage blocking region 8 and the voltage blocking region 3 and the contact region 5a and 5b.

FIG. 3B is a cross-sectional view illustrating a region in a case of including a polysilicon resistor 25 that corresponds to the resistor R11 illustrated in FIG. 3A. An insulating film 9a is deposited on the respective top surfaces of the well region 2, the contact region 5c, the isolation region 6, the voltage blocking region 8, and the contact region 5b. The polysilicon resistor 25 is provided on the top surface of the insulating film 9a. The polysilicon resistor 25 includes polysilicon heavily doped with p-type or n-type impurity ions. An insulating film 9b is deposited to cover the top surface of the insulating film 9a and the respective top and side surfaces of the polysilicon resistor 25. Metal wiring layers 26a and 26b are provided on the top surface of the insulating film 9b. The metal wiring layer 26a connects the contact region 5b to one end of the polysilicon resistor 25 through openings (contact holes) provided in the respective insulating films 9a and 9b. The metal wiring layer 26b connects the contact region 5c to the other end of the polysilicon resistor 25 through openings (contact holes) provided in the respective insulating films 9a and 9b.

FIG. 3C is a cross-sectional view illustrating a region in a case of including a diffusion resistor (a diffusion layer) 27 that corresponds to the resistor R11 illustrated in FIG. 3A. The p-type diffusion resistor 27 is provided at the upper part of the well region 2. Contact regions 28a and 28b of p⁺-type having a higher impurity concentration than the diffusion resistor 27 are provided separately from each other at the upper part of the diffusion resistor 27. The diffusion resistor 27 interposed between the respective contact regions 28a and 28b serves as a resistor. The insulating film 9a is deposited on the respective top surfaces of the well region 2, the contact regions 28a and 28b, the contact region 5c, the isolation region 6, the voltage blocking region 8, and the contact region 5b. Metal wiring layers 29a and 29b are provided on the top surface of the insulating film 9a. The metal wiring layer 29a connects the contact region 5b to the contact region 28a through openings (contact holes) provided in the insulating film 9a. The metal wiring layer 29b connects the contact region 5c to the contact region 28b through openings (contact holes) provided in the insulating film 9a.

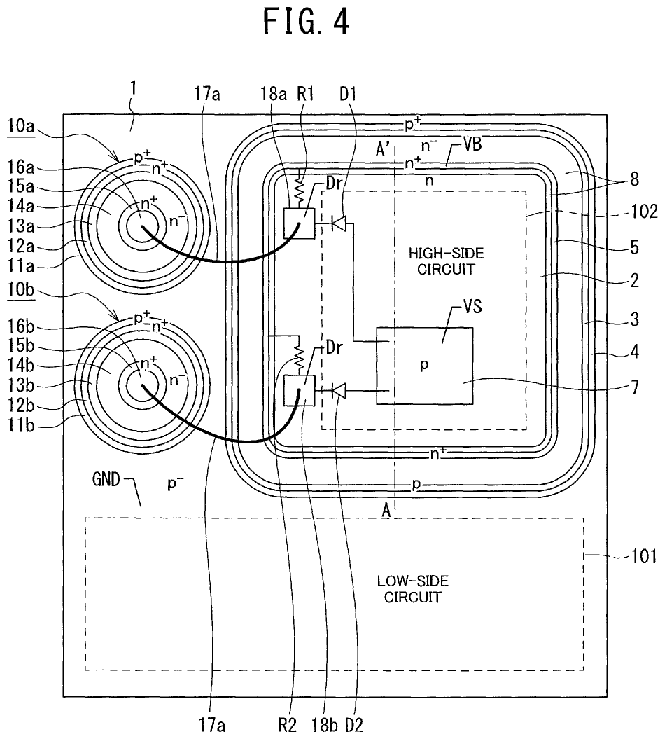

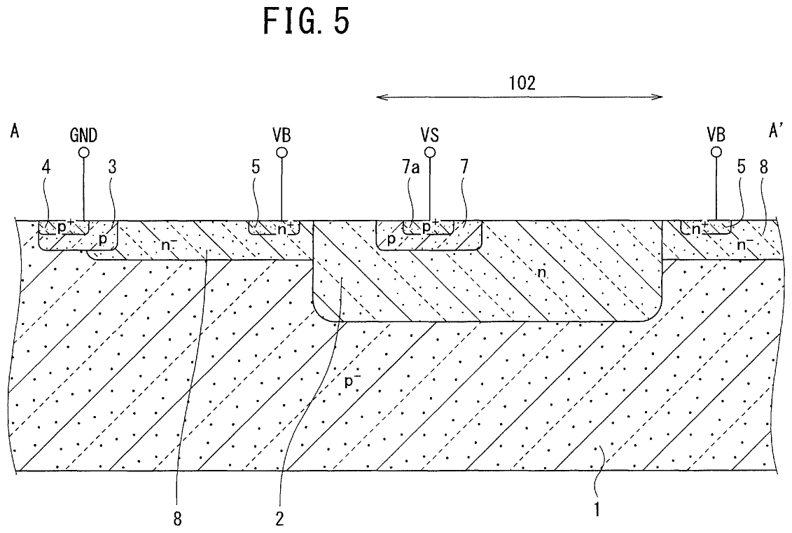

FIG. 4 illustrates a planar layout of a semiconductor device of a comparative example of the first embodiment, and FIG. 5 is a cross-sectional view taken along line A-A′ in FIG. 4. As illustrated in FIG. 4 and FIG. 5, the semiconductor device of the comparative example differs from the semiconductor device according to the first embodiment illustrated in FIG. 2 and FIG. 3 in that the voltage blocking region 8 is not provided with the p⁻-type isolation region 6. The voltage blocking region 8 has a circular planar pattern. The contact region 5 having a circular shape is provided at the upper part of the voltage blocking region 8. The VB potential is applied to the contact region 5.

The configuration of the semiconductor device of the comparative example of the first embodiment can cause a phenomenon in which, when the VB potential or the VS potential steeply rises up due to the ESD, for example, the potential of the voltage blocking region 8 that is led to be the same potential as the VB potential or the VS potential also rises up, and the potential of the substrate body 1 (the substrate potential) immediately under the voltage blocking region 8 further rises up when a displacement current flows through the substrate body 1. Particularly when the potential (the rear surface potential) on the bottom surface of the substrate body 1 is not fixed, the fluctuation of the substrate potential significantly occurs. Further, if the low-side circuit 101 is located close to the voltage blocking region 8, the fluctuation of the substrate potential is transmitted to induce a parasitic operation, which could cause a reduction in noise tolerance such as ESD tolerance accordingly.

In contrast, the semiconductor device according to the first embodiment has the configuration in which the opposed part 8a of the voltage blocking region 8 opposed to the low-side circuit 101 is insulated from the VB potential and the VS potential, while the opposed part 8a is connected to the VB potential and the VS potential via the respective resistors R11 and R12, as illustrated in FIG. 2 and FIG. 3A. This configuration does not lead the opposed part 8a to easily follow the steep rise of the VB potential or the VS potential, so as to avoid or decrease the rise of the substrate potential around the opposed part 8a. The configuration described above thus can suppress the fluctuation of the substrate potential without the chip area increased, improving the noise tolerance such as ESD tolerance accordingly.

### Second Embodiment

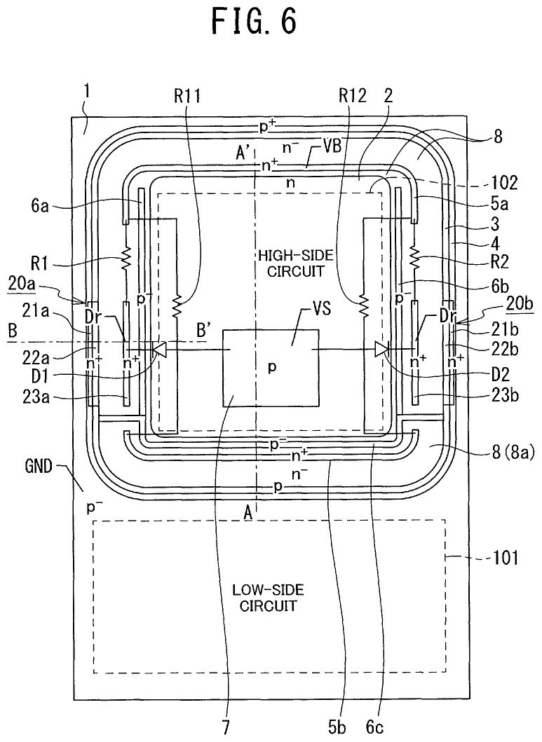

A semiconductor device according to a second embodiment differs from the semiconductor device according to the first embodiment illustrated in FIG. 2 in including level-shift elements 20a and 20b provided by the SS method, as illustrated in FIG. 6. The level-shift elements 20a and 20b respectively correspond to the level-shift elements T1 and T2 illustrated in FIG. 1. The respective level-shift elements 20a and 20b are formed integrally with a part of the HVJT (3, 8) implemented by the n⁻-type voltage blocking region 8 and the p-type voltage blocking region 3. The respective level-shift elements 20a and 20b are located on the different sides of the rectangular planar pattern of the HVJT (3, 8) so as to be opposed to each other.

The level-shift element 20a includes a source region 21a of n⁺-type, a gate electrode 22a, and a drain region 23a of n⁺-type. The source region 21a, the gate electrode 22a, and the drain region 23a each have a straight planar pattern extending parallel to each other. A part of the voltage blocking region 8 interposed between the source region 21a and the drain region 23a serves as a drift region of the level-shift element 20a. The VB potential of the contact region 5a is connected to the drain region 23a via the level-shift resistor R1. The VS potential of the p-type well region 7 is connected to the drain region 23a via the diode D1.

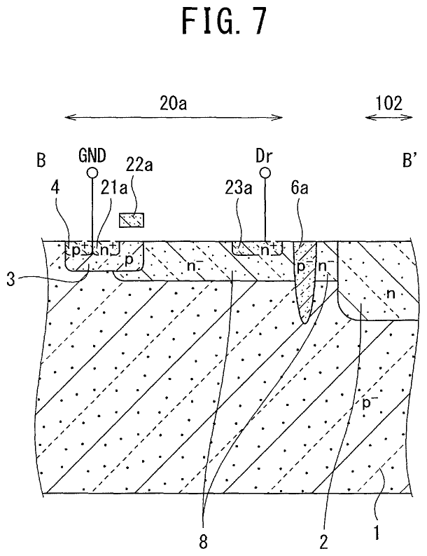

FIG. 7 is a cross-sectional view taken along line B-B′ passing through the level-shift element 20a in FIG. 6. As illustrated in FIG. 7, the level-shift element 20a is insulated from the n-type well region 2 by a isolation region 6a of p⁻-type. The drain region 23a is provided at the upper part of the voltage blocking region 8 serving as the drift region of the level-shift element 20a. The p-type voltage blocking region 3, which is in contact with the voltage blocking region 8 serving as the drift region of the level-shift element 20a, serves as a base region of the level-shift element 20a. The source region 21a and the contact region 4 are provided at the upper part of the voltage blocking region 3. The gate electrode 22a is provided over the voltage blocking region 3 interposed between the source region 21a and the voltage blocking region 8 with a gate insulating film (not illustrated) interposed.

The level-shift element 20b illustrated in FIG. 6 has a configuration similar to that of the level-shift element 20a. The level-shift element 20b includes a source region 21b of n⁺-type, a gate electrode 22b, and a drain region 23b of n⁺-type. The source region 21b, the gate electrode 22b, and the drain region 23b each have a straight planar pattern extending parallel to each other. A part of the voltage blocking region 8 interposed between the source region 21b and the drain region 23b serves as a drift region of the level-shift element 20b. The VB potential of the contact region 5b is connected to the drain region 23b via the level-shift resistor R2. The VS potential of the p-type well region 7 is connected to the drain region 23b via the diode D2.

The semiconductor device according to the second embodiment includes isolation regions (slit regions) 6a to 6c of p⁻-type provided to surround the circumference of the high-side circuit 102, as illustrated in FIG. 6. The isolation regions 6a to 6c entirely have a substantially U-shaped planar pattern having an opening on the upper side.

The isolation region 6a is provided between the well region 2 and the level-shift element 20a, and has a straight planar pattern. The isolation region 6a isolates the level-shift element 20a from the well region 2. The isolation region 6b is arranged between the well region 2 and the level-shift element 20b, and has a straight planar pattern. The isolation region 6b isolates the level-shift element 20b from the well region 2.

The isolation region 6c has a substantially Ω-shaped planar pattern having an opening on the upper side. The both ends of the isolation region 6c are in contact with the voltage blocking region 3. Each one end of the isolation regions 6a and 6b is in contact with a stepped part of the planar pattern of the isolation region 6c. The isolation region 6c electrically isolates the part (the opposed part) 8a of the voltage blocking region 8 opposed to the low-side circuit 101 from the well region 2.

The opposed part 8a has a substantially U-shaped planar pattern having an opening on the upper side. The n⁺-type contact region 5b is provided at the upper part of the opposed part 8a. The contact region 5b differs from the contact region 5a in not being applied with the VB potential. The VB potential of the contact region 5a is connected to the contact region 5b via the respective resistors R11 and R12. The resistors R11 and R12 are each a polysilicon resistor provided over the substrate body 1, for example. The cross section taken along line A-A′ in FIG. 6 is the same as the cross section of the semiconductor device according to the first embodiment illustrated in FIG. 3A. The isolation region 6 of the semiconductor device according to the first embodiment illustrated in the cross-sectional view of FIG. 3A corresponds to the isolation region 6c illustrated in the cross-sectional view taken along line A-A′ in FIG. 6. The other configurations of the semiconductor device according to the second embodiment are the same as those of the semiconductor device according to the first embodiment, and overlapping explanations are not repeated below.

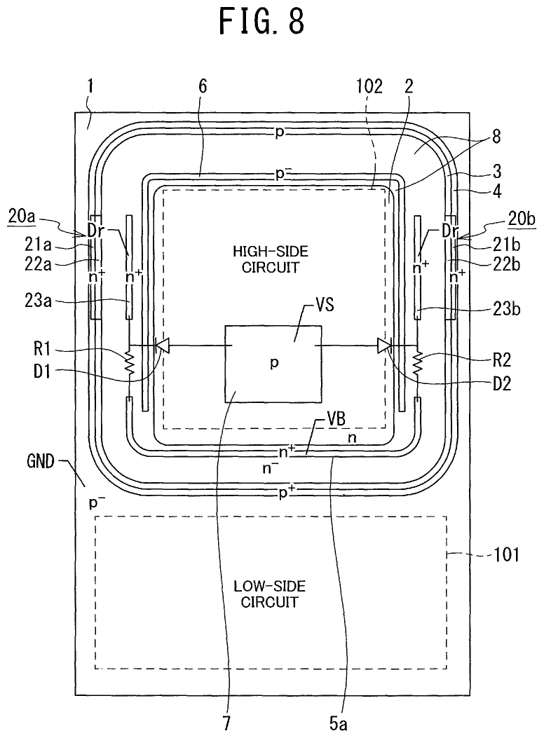

FIG. 8 illustrates a planar layout of a semiconductor device of a comparative example of the second embodiment. As illustrated in FIG. 8, the semiconductor device of the comparative example differs from the semiconductor device according to the second embodiment illustrated in FIG. 6 in including the p⁻-type isolation region 6 having a U-shaped planar pattern having an opening on the lower side so as to surround the circumference of the high-side circuit 102, and in including the contact region 5a on the low-side circuit 101 side to which the VB potential is applied. The isolation region 6 isolates the high-side circuit 102 from the respective level-shift elements 20a and 20b. The voltage blocking region 8 has a substantially circular planar pattern. The part of the voltage blocking region 8 toward the low-side circuit 101 is not electrically isolated from the well region 2.

In the semiconductor device of the comparative example of the second embodiment, the potential of the part of the voltage blocking region 8 opposed to the low-side circuit 101 tends to easily follow the VB potential or the VS potential to rise up. This configuration can cause a phenomenon in which, when the VB potential or the VS potential steeply rises up due to the ESD, for example, the potential of the voltage blocking region 8 that is led to be the same potential as the VB potential or the VS potential also rises up, and the potential of the substrate body 1 (the substrate potential) immediately under the voltage blocking region 8 further rises up when a displacement current flows through the substrate body 1. If the low-side circuit 101 is located close to the voltage blocking region 8, the fluctuation of the substrate potential is transmitted to induce a parasitic operation, which could cause a reduction in noise tolerance such as ESD tolerance accordingly.

In contrast, the semiconductor device according to the second embodiment has the configuration in which the opposed part 8a of the voltage blocking region 8 opposed to the low-side circuit 101 is isolated from the VB potential and the VS potential, while the opposed part 8a is connected to the VB potential and the VS potential via the respective resistors R11 and R12, as illustrated in FIG. 6. This configuration does not lead the opposed part 8a to easily follow the steep rise of the VB potential or the VS potential, so as to avoid or decrease the rise of the substrate potential around the opposed part 8a. The configuration described above thus can suppress the fluctuation of the substrate potential without the chip area increased, improving the noise tolerance such as ESD tolerance accordingly.

### Third Embodiment

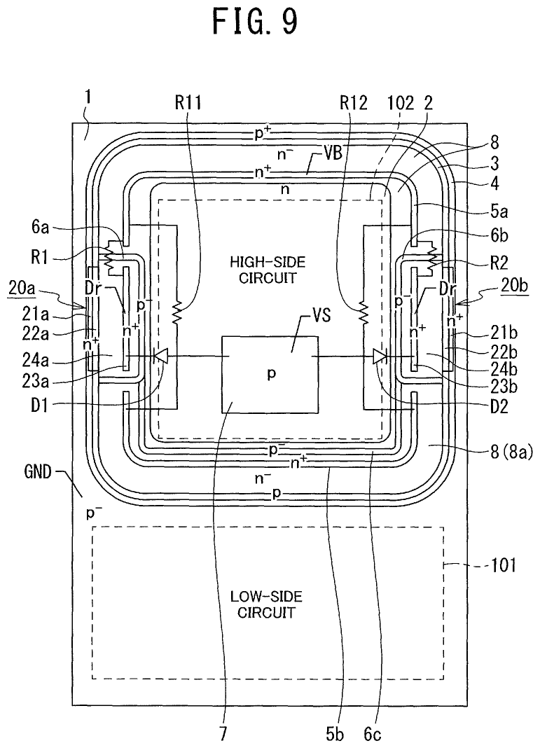

A semiconductor device according to a third embodiment differs from the semiconductor device according to the second embodiment illustrated in FIG. 6 in that the respective circumferences of the level-shift elements 20a and 20b obtained by the SS method are surrounded by the p⁻-type isolation regions (slit regions) 6a and 6b, as illustrated in FIG. 9.

The isolation region 6a has a substantially U-shaped planar pattern so as to surround the circumference of the level-shift element 20a. The both ends of the isolation region 6a are in contact with the voltage blocking region 3. The provision of the isolation region 6a surrounding the circumference of the level-shift element 20a electrically isolates the Dr potential of the drain region 23a of the level-shift element 20a from the VB potential of the contact region 5a, and also electrically isolates the drift region 24a of the level-shift element 20a from the voltage blocking region 8.

The isolation region 6b has a substantially U-shaped planar pattern so as to surround the circumference of the level-shift element 20b. The both ends of the isolation region 6b are in contact with the voltage blocking region 3. The provision of the isolation region 6b surrounding the circumference of the level-shift element 20b electrically isolates the Dr potential of the drain region 23b of the level-shift element 20b from the VB potential of the contact region 5a, and also electrically isolates the drift region 24b of the level-shift element 20b from the voltage blocking region 8.

The contact region 5a is connected to the drain region 23a of the level-shift element 20a via the level-shift resistor R1 which is a polysilicon resistor, for example. The VS potential of the p-type well region 7 is connected to the drain region 23a of the level-shift element 20a via the diode D1.

The contact region 5a is connected to the drain region 23b of the level-shift element 20b via the level-shift resistor R2 which is a polysilicon resistor, for example. The VS potential of the p-type well region 7 is connected to the drain region 23b of the level-shift element 20b via the diode D2.

The isolation region 6c has a substantially U-shaped planar pattern having an opening on the upper side so as to surround the circumference of the high-side circuit 102. One end of the isolation region 6c is in contact with the isolation region 6a, and the other end is in contact with the isolation region 6b. The provision of the respective isolation regions 6a to 6c isolates the part (the opposed part) 8a of the voltage blocking region 8 opposed to the low-side circuit 101 from the well region 2.

The opposed part 8a has a substantially U-shaped planar pattern having an opening on the upper side so as to surround the circumference of the high-side circuit 102. The contact region 5b is provided at the upper part of the opposed part 8a. The contact region 5b differs from the contact region 5a in not being applied with the VB potential. The contact region 5a is connected to the contact region 5b via the respective resistors R11 and R12. The other configurations of the semiconductor device according to the third embodiment are the same as those of the semiconductor device according to the second embodiment, and overlapping explanations are not repeated below.

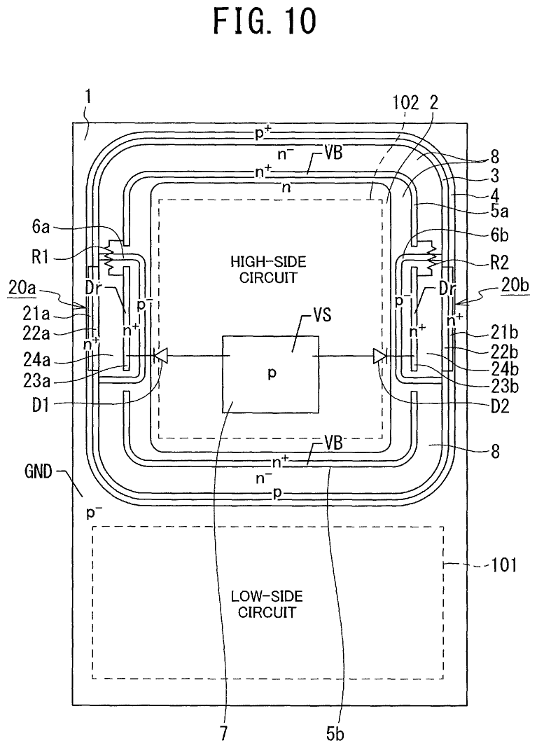

FIG. 10 illustrates a planar layout of a semiconductor device of a comparative example of the third embodiment. As illustrated in FIG. 10, the semiconductor device of the comparative example differs from the semiconductor device according to the third embodiment illustrated in FIG. 9 in not including the p⁻-type isolation region 6c or the respective resistors R11 and R12, and in applying the VB potential further to the contact region 5b.

In the semiconductor device of the comparative example of the third embodiment, the potential of the part of the voltage blocking region 8 opposed to the low-side circuit 101 tends to easily follow the VB potential or the VS potential to rise up. This configuration can cause a phenomenon in which, when the VB potential or the VS potential steeply rises up due to the ESD, for example, the potential of the voltage blocking region 8 that is led to be the same potential as the VB potential or the VS potential also rises up, and the potential of the substrate body 1 (the substrate potential) immediately under the voltage blocking region 8 further rises up when a displacement current flows through the substrate body 1. If the low-side circuit 101 is located close to the voltage blocking region 8, the fluctuation of the substrate potential is transmitted to induce a parasitic operation, which could cause a reduction in noise tolerance such as ESD tolerance accordingly.

In contrast, the semiconductor device according to the third embodiment has the configuration in which the opposed part 8a of the voltage blocking region 8 opposed to the low-side circuit 101 is isolated from the VB potential and the VS potential, while the opposed part 8a is connected to the VB potential and the VS potential via the respective resistors R11 and R12, as illustrated in FIG. 9. This configuration does not lead the opposed part 8a to easily follow the steep rise of the VB potential or the VS potential, so as to avoid or decrease the rise of the substrate potential around the opposed part 8a. The configuration described above thus can suppress the fluctuation of the substrate potential without the chip area increased, improving the noise tolerance such as ESD tolerance accordingly.

### Fourth Embodiment

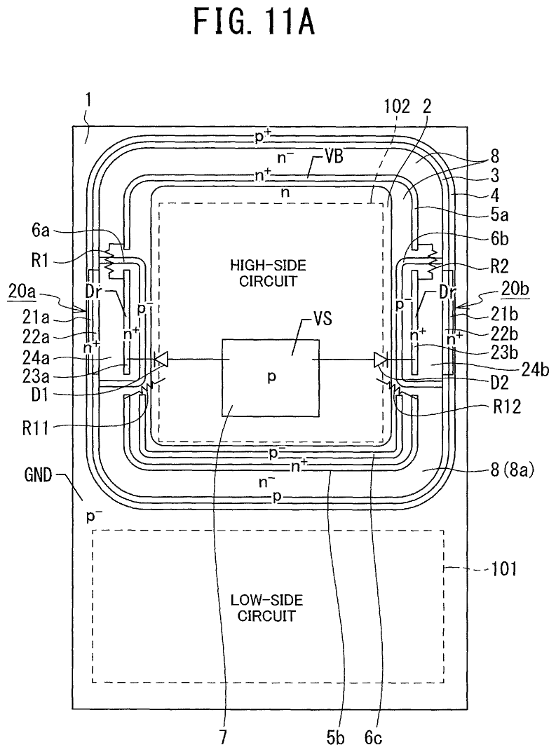

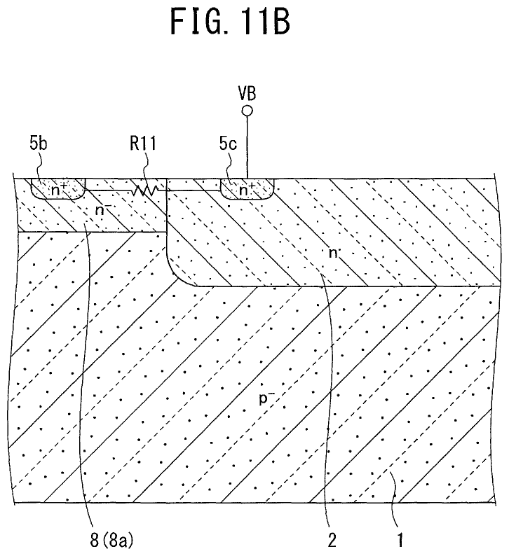

A semiconductor device according to a fourth embodiment differs from the semiconductor device according to the third embodiment illustrated in FIG. 9 in that the p⁻-type isolation region 6c is not in contact with the respective p⁻-type isolation regions 6a and 6b, and in that the respective resistors R11 and R12 are each a diffusion resistor, as illustrated in FIG. 11A.

The semiconductor device according to the fourth embodiment includes the isolation region 6c having a substantially U-shaped planar pattern provided with an opening on the upper side so as to surround the circumference of the high-side circuit 102. The respective both ends of the isolation region 6c are not in contact with the isolation regions 6a and 6b but are separated from the isolation regions 6a and 6b by a predetermined gap.

The contact region 5b provided at the upper part of the opposed part 8a is electrically connected to the well region 2 via the respective resistors R11 and R12. The resistors R11 and R12 are each a diffusion resistor of the well region 2.

FIG. 11B is a cross-sectional view illustrating a region including the resistor R11 illustrated in FIG. 11A. The n⁺-type contact region 5c having a higher impurity concentration than the well region 2 is provided at the upper part of the well region 2. The n-type voltage blocking region 8 is provided to be in contact with the well region 2. The n⁺-type contact region 5b having a higher impurity concentration than the voltage blocking region 8 is provided at the upper part of the voltage blocking region 8. The well region 2 and the voltage blocking region 8 interposed between the contact region 5b and the contact region 5c implement the resistor R11. The other configurations of the semiconductor device according to the fourth embodiment are the same as those of the semiconductor device according to the third embodiment, and overlapping explanations are not repeated below.

The semiconductor device according to the fourth embodiment has the configuration in which the p⁻-type isolation region 6c is not in contact with the respective p⁻-type isolation regions 6a and 6b, and in which the respective resistors R11 and R12 are each the diffusion resistor. This configuration also does not lead the opposed part 8a to easily follow the steep rise of the VB potential or the VS potential, so as to avoid or decrease the rise of the substrate potential around the opposed part 8a. The configuration described above thus can suppress the fluctuation of the substrate potential without the chip area increased, improving the noise tolerance such as ESD tolerance accordingly.

### Fifth Embodiment

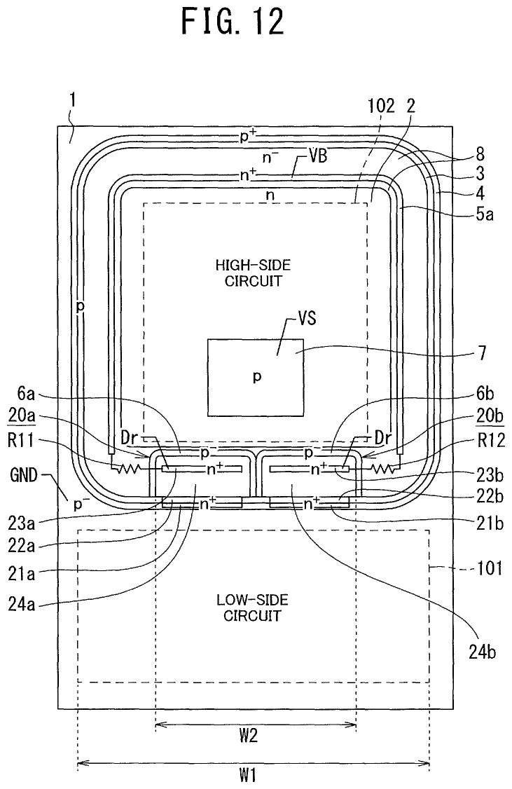

A semiconductor device according to a fifth embodiment differs from the semiconductor device according to the third embodiment illustrated in FIG. 9 in that the respective level-shift elements 20a and 20b obtained by the SS method are arranged on one of the four sides of the rectangular planar pattern of the HVJT (3, 8) opposed to the low-side circuit 101, as illustrated in FIG. 12.

A width W2 of the level-shift elements 20a and 20b is narrower than the width W1 of the low-side circuit 101. The p⁻-type isolation regions (the slit regions) 6a and 6b are provided to surround the respective circumferences of the level-shift elements 20a and 20b. The isolation regions 6a and 6b are in contact with each other. While FIG. 12 illustrates the case in which the two isolation regions 6a and 6b are provided between the respective level-shift elements 20a and 20b, the semiconductor device according to the present embodiment may include a single common isolation region. When the isolation regions 6a and 6b are separated from each other, another p⁻-type isolation region may be further provided so as to connect the respective isolation regions 6a and 6b to each other.

The n⁺-type contact region (the pickup region) 5a is provided at the upper part of the well region 2. The contact region 5a has a substantially U-shaped planar pattern provided with an opening on the lower side so as to surround the circumference of the high-side circuit 102. The VB potential is applied to the contact region 5a.

The drift region 24a of the level-shift element 20a is composed of a part of the voltage blocking region 8. The VB potential of the contact region 5a is connected to the drain region 23a of the level-shift element 20a via the resistor R11 such as a polysilicon resistor. No diode is connected between the drain region 23a of the level-shift element 20a and the VS potential of the p-type well region 7.

The drift region 24b of the level-shift element 20b is composed of a part of the voltage blocking region 8. The VB potential of the contact region 5a is connected to the drain region 23b of the level-shift element 20b via the resistor R12 such as a polysilicon resistor. No diode is connected between the drain region 23b of the level-shift element 20b and the VS potential of the p-type well region 7.

The semiconductor device according to the fifth embodiment has the configuration in which the isolation regions 6a and 6b surrounding the respective circumferences of the level-shift elements 20a and 20b isolate the drift regions 24a and 24b of the level-shift elements 20a and 20b from the voltage blocking region 8. In other words, the drift regions 24a and 24b are each the opposed part of the voltage blocking region 8 opposed to the low-side circuit 101 isolated from the well region 2. The drift regions 24a and 24b correspond to at least the middle of the part of the voltage blocking region 8 opposed to the low-side circuit 101. The other configurations of the semiconductor device according to the fifth embodiment are the same as those of the semiconductor device according to the third embodiment illustrated in FIG. 9, and overlapping explanations are not repeated below.

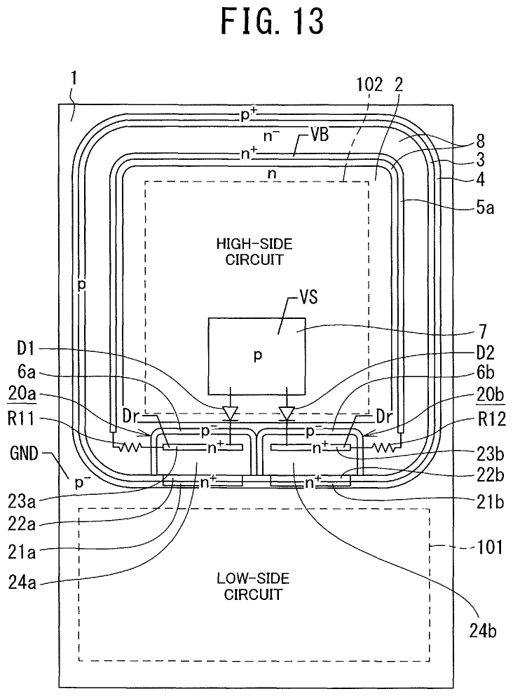

FIG. 13 illustrates a planar layout of a semiconductor device of a comparative example of the fifth embodiment. As illustrated in FIG. 13, the semiconductor device of the comparative example differs from the semiconductor device according to the fifth embodiment illustrated in FIG. 12 in that the diodes D1 and D2 are connected between the drain regions 23a and 23b of the level-shift elements 20a and 20b and the p-type well region 7. The respective diodes D1 and D2 have a function of avoiding an excessive decrease of the Dr potential of the drain regions 23a and 23b of the level-shift elements 20a and 20b.

The configuration of the comparative example, in which the diodes D1 and D2 are connected between the drain regions 23a and 23b of the level-shift elements 20a and 20b and the p-type well region 7, tends to lead the Dr potential of the respective drain regions 23a and 23b to easily follow the VS potential applied to the well region 7 to rise up. When the VS potential steeply rises up due to the ESD, for example, the potential of the respective drift regions 24a and 24b also rises up, and the potential of the substrate body 1 (the substrate potential) immediately under the drift regions 24a and 24b further rises up when a displacement current flows through the substrate body 1. This leads the fluctuation of the substrate potential to be transmitted to induce a parasitic operation, which could cause a reduction in noise tolerance such as ESD tolerance.

In contrast, the semiconductor device according to the fifth embodiment has the configuration in which the drift regions 24a and 24b of the level-shift elements 20a and 20b each implementing a part of the voltage blocking region 8 are opposed to the low-side circuit 101, and in which the drain regions 23a and 23b of the level-shift elements 20a and 20b are not connected to the VS potential of the p-type well region 7 via the diodes. The Dr potential of the drain regions 23a and 23b is thus connected only to the VB potential of the contact region 5a via the resistors R11 and R12. This configuration does not lead the drift regions 24a and 24b to easily follow the steep rise of the VB potential or the VS potential, so as to avoid or decrease the rise of the substrate potential around the drift regions 24a and 24b. The configuration described above thus can suppress the fluctuation of the substrate potential without the chip area increased, improving the noise tolerance such as ESD tolerance accordingly.

### Sixth Embodiment

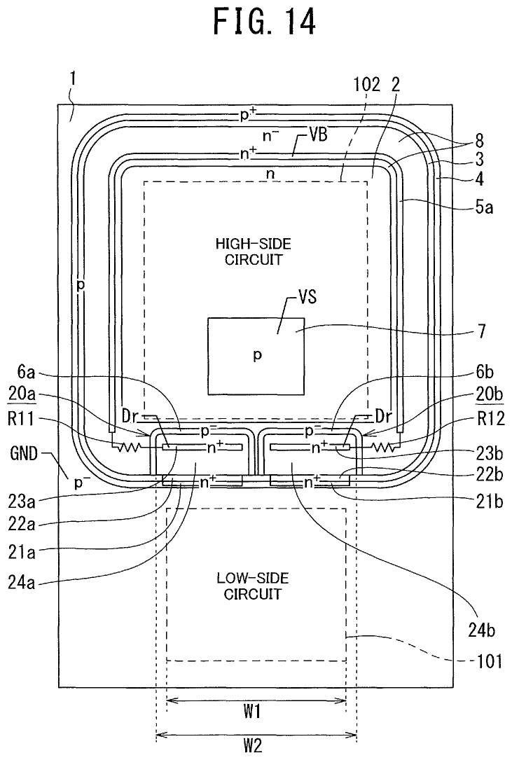

A semiconductor device according to a sixth embodiment differs from the semiconductor device according to the fifth embodiment illustrated in FIG. 12 in that the width W1 of the low-side circuit 101 is narrower than the width W2 of the level-shift elements 20a and 20b opposed to the low-side circuit 101, as illustrated in FIG. 14.

While FIG. 14 illustrates the case in which the width W1 of the low-side circuit 101 is narrower than the width W2 of the level-shift elements 20a and 20b, the width W1 of the low-side circuit 101 and the width W2 of the level-shift elements 20a and 20b may conform to each other. The semiconductor device according to the sixth embodiment also has a configuration in which the drift regions 24a and 24b of the level-shift elements 20a and 20b are each the opposed part of the voltage blocking region 8 opposed to the low-side circuit 101. The other configurations of the semiconductor device according to the sixth embodiment are the same as those of the semiconductor device according to the fifth embodiment, and overlapping explanations are not repeated below.

The semiconductor device according to the sixth embodiment has the configuration in which the width W1 of the low-side circuit 101 is set to be smaller than or equal to the width W2 of the level-shift elements 20a and 20b opposed to the low-side circuit 101, as described above. This configuration leads the entire part of the voltage blocking region 8 opposed to the low-side circuit 101 to be isolated from the VB potential and the VS potential, but is connected to the VB potential and the VS potential via the respective resistors R11 and R12. The opposed part thus hardly follows the steep rise of the VB potential or the VS potential, so as to avoid or decrease the rise of the substrate potential around the opposed part. The configuration described above thus can suppress the fluctuation of the substrate potential without the chip area increased, improving the noise tolerance such as ESD tolerance accordingly.

### Seventh Embodiment

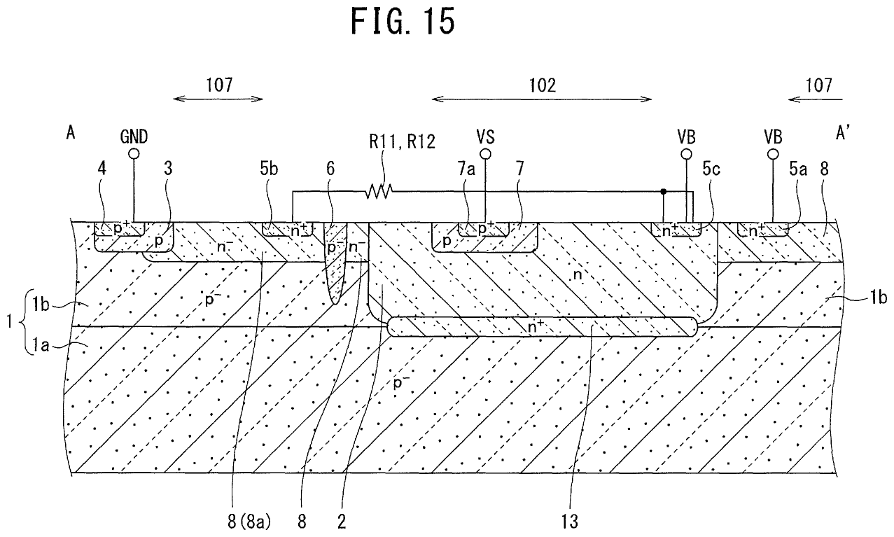

A semiconductor device according to a seventh embodiment differs from the semiconductor device according to the first embodiment illustrated in FIG. 3A in that the substrate body 1 is composed of a semiconductor substrate 1a of p⁻-type and an epitaxial layer 1b of p⁻-type deposited on the semiconductor substrate 1a, as illustrated in FIG. 15.

The semiconductor device according to the seventh embodiment further differs from the semiconductor device according to the first embodiment illustrated in FIG. 3A in that a buried layer 13 of n⁺-type having a higher impurity concentration than the well region 2 is provided in contact with the bottom surface of the well region 2. The buried layer 13 is deposited uniformly in the horizontal direction along the bottom surface of the well region 2. The buried layer 13 has a function of suppressing the operation of a pnp bipolar transistor implemented by an internal circuit of the well region 2 in the depth direction. The other configurations of the semiconductor device according to the seventh embodiment are the same as those of the semiconductor device according to the first embodiment, and overlapping explanations are not repeated below.

The semiconductor device according to the seventh embodiment has the configuration in which the opposed part 8a of the voltage blocking region 8 opposed to the low-side circuit 101 is isolated from the VB potential and the VS potential, while the opposed part 8a is connected to the VB potential and the VS potential via the respective resistors R11 and R12, as in the case of the semiconductor device according to the first embodiment. This configuration does not lead the opposed part 8a to easily follow the steep rise of the VB potential or the VS potential, so as to avoid or decrease the rise of the substrate potential around the opposed part 8a. The configuration described above thus can suppress the fluctuation of the substrate potential without the chip area increased, improving the noise tolerance such as ESD tolerance accordingly.

### Other Embodiments

As described above, the invention has been described according to the first to seventh embodiments, but it should not be understood that the description and drawings implementing a portion of this disclosure limit the invention. Various alternative embodiments of the present invention, examples, and operational techniques will be apparent to those skilled in the art from this disclosure.

While the respective first to seventh embodiments have been illustrated with the semiconductor device including the high-side circuit 102 for a single phase, the present invention may also be applied to a semiconductor device including high-side circuits for three phases. When the semiconductor device includes high-side circuits for three phases, the opposed part of the n⁻-type voltage blocking region opposed to the low-side circuit may be isolated from the VB potential and the VS potential by the p⁻-type isolation region in each of the high-side circuits for the three phases.

The respective configurations disclosed in the first to seventh embodiments of the present invention and the respective modified examples can be combined together as necessary within a range without contradicting each other. As described above, the invention includes various embodiments of the present invention and the like not described herein. Therefore, the scope of the present invention is defined only by the technical features specifying the present invention, which are prescribed by claims, the words and terms in the claims shall be reasonably construed from the subject matters recited in the present specification.

What is claimed is:

1. A semiconductor device comprising:
a substrate body of a first conductivity-type;
a first well region of a second conductivity-type provided in the substrate body and provided with a high-side circuit;
a first voltage blocking region of the second conductivity-type provided around the first well region and having a lower impurity concentration than the first well region;
a contact region of the second conductivity-type provided at an upper part of the first well region or the first voltage blocking region and having a higher impurity concentration than the first well region;
a second voltage blocking region of the first conductivity-type provided on an outer circumferential side of the first voltage blocking region so as to be in contact with the first voltage blocking region;
a first isolation region of the first conductivity-type provided to electrically isolate, from the first well region, an opposed part of the first voltage blocking region opposed to a low-side circuit provided on an outer circumferential side of the second voltage blocking region; and
a level shifter provided to execute a signal transmission between the low-side circuit and the high-side circuit.

2. The semiconductor device of claim 1, further comprising a resistor arranged to connect the opposed part and the contact region to each other.

3. The semiconductor device of claim 1, further comprising:
a second well region of the first conductivity-type provided at the upper part of the first well region; and
a diode connected between the second well region and a carrier-reception region of the level shifter.

4. The semiconductor device of claim 2, wherein the resistor is a polysilicon resistor.

5. The semiconductor device of claim 2, wherein the resistor is a diffusion resistor.

6. The semiconductor device of claim 1, wherein the level shifter is provided on the outer circumferential side of the second voltage blocking region.

7. The semiconductor device of claim 1, wherein:
the first voltage blocking region has an outline with a rectangular shape in a planar pattern; and
the opposed part includes two corners toward the low-side circuit among four corners of the rectangular shape.

8. The semiconductor device of claim 1, further comprising a level-shift resistor connected between a carrier-reception region of the level shifter and the contact region.

9. The semiconductor device of claim 1, wherein both ends of the isolation region are in contact with the second voltage blocking region.

10. The semiconductor device of claim 1, wherein the opposed part includes an entire part of the first voltage blocking region opposed to the low-side circuit.

11. The semiconductor device of claim 1, wherein the opposed part includes at least a middle of a part of the first voltage blocking region opposed to the low-side circuit.

12. The semiconductor device of claim 1, wherein the level shifter is provided integrally with a part of each of the first voltage blocking region and the second voltage blocking region.

13. The semiconductor device of claim 12, wherein:
the first voltage blocking region has an outline with a rectangular shape in a planar pattern; and
the level shifter is provided on one of four sides of the rectangular shape not opposed to the low-side circuit.

14. The semiconductor device of claim 13, further comprising a second isolation region of the first conductivity-type provided to isolate a drift region of the level shifter from the first voltage blocking region and isolate a carrier-reception region of the level shifter from the contact region.

15. The semiconductor device of claim 14, wherein the second isolation region and the first isolation region are connected to each other.

16. The semiconductor device of claim 12, wherein:
the level shifter is provided to be opposed to the low-side circuit;
a drift region of the level shifter is implemented by the first voltage blocking region and serves as the opposed part; and
the first isolation region isolates the level shifter from the first well region.

17. The semiconductor device of claim 16, wherein a carrier-reception region of the level shifter is connected only to the contact region via a resistor.

18. The semiconductor device of claim 16, wherein a width of the low-side circuit is smaller than or equal to a width of the level shifter.
